(19) United States
(12) Patent Application Publication
(10) Pub. No.: US 2008/0089151 A1
(43) Pub. Date: Apr. 17, 2008

(54) Methods of determining laser alignment and related structures, devices, and circuits

(75) Inventors: Jae-young Kim, Seoul (KR); Joo-sung Park, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/890,658

(22) Filed: Aug. 7, 2007

(30) Foreign Application Priority Data
Oct. 17, 2006 (KR) 2006-0101025

(51) Int. Cl. G11C 7/00; H01L 21/66; H01L 23/544; H01L 23/58

(52) U.S. Cl. 365/200; 257/48; 257/797; 365/225.7; 438/17; 257/E23.179; 257/E21.521

(57) ABSTRACT

Methods may be provided to determine an alignment of a laser with respect to an integrated circuit device including a fuse pattern and a monitoring pattern adjacent the fuse pattern. More particularly, the fuse pattern may be cut with radiation from the laser. After cutting the fuse pattern, an electrical signal through the monitoring pattern may be measured to determine an alignment of radiation from the laser with respect to the fuse pattern. Related structures, devices, and circuits are also discussed.

### RELATED PATENT APPLICATION

This application claims the benefit of Korean Patent Application No. 10-2006-0101025, filed on Oct. 17, 2006, in the Korean Intellectual Property Office, the disclosure of which is incorporated herein in its entirety by reference.

### FIELD OF THE INVENTION

The present invention relates to semiconductor devices, and more particularly, to fuse structures for semiconductor devices.

### BACKGROUND OF THE INVENTION

As semiconductor devices such as dynamic random access memories (DRAMs) become more highly integrated, an occurrence of memory cell defects may increase and a production yield of the devices may thus decrease. To improve yield, a redundant circuit may be used to repair the device. When a defective memory cell is detected in a memory cell array during a test process, a fuse in a fuse box arranged in a peripheral circuit region of a semiconductor device may be cut, and then, the defective memory cell may be replaced with a corresponding redundant memory cell. Thus, the semiconductor device may perform normally since the defective memory cell is replaced with a redundant memory cell.

FIG. 1 is a plan view illustrating a fuse box used to repair a defect in a conventional semiconductor device. A fuse box 10 may include a plurality of fuses 15 arranged at a pitch P. The fuses 15 may be exposed through a fuse opening 13 to be cut using laser irradiation. The fuse opening 13 may be defined by a metal interconnection 17 surrounding it. The metal interconnection 17 may be covered with a photosensitive polyimide layer (PSPl) as a passivation layer (not shown in FIG. 1).

The fuses 15 may each have a width W and may be arranged at the pitch P. Each of the fuses 15 may be initially provided in a conductive state and may go into a non-conductive state when cut. The fuses 15 may be cut using a laser beam 19 defining a spot size S. The spot size S may be large enough to cover the fuse 15 so that the fuse can absorb laser energy and be cut by the laser beam 19. Moreover, the fuse pitch P may be greater than an error tolerance of position accuracy of the laser beam.

As semiconductor devices become more highly integrated, a number of fuses used to repair a semiconductor device may increase while a pitch P and a width W of the fuses may decrease. When a laser beam having a spot size S is misaligned in cutting a fuse with the laser beam, a cutting defect may be generated. If the laser beam 19 is misaligned when a desired fuse 15a of the plurality of fuses 15 is cut, a fuse 15b (not intended to be cut) adjacent to the fuse 15a (in a width direction of the fuse 15a) may be cut. Meanwhile, referring to FIG. 2, if the laser beam 19 is misaligned, a cut portion 15d of the fuse 15a may be adjacent to the metal interconnection 17 in a length direction of the fuse 15a. In this case, a photosensitive polyimide 20 on the metal interconnection 17 may be removed to expose the metal interconnection 17, and a defect such as a bridge may be generated between the exposed metal interconnection 17 and the fuse 15a by a fuse cutting material 15c.

After a laser repair operation, an accurate discrimination of a cutting defect caused by laser misalignment may be difficult and time-consuming because the inspection may be made visually by an operator. In addition, since an inspection to see if the fuse is cut is made after a repair process is completed, a repair may not be effective if cannot be normally made when a cutting defect is generated.

### SUMMARY OF THE INVENTION

According to some embodiments of the present invention, methods may be provided to determine an alignment of a laser with respect to an integrated circuit device including a fuse pattern and a monitoring pattern adjacent the fuse pattern. More particularly, the fuse pattern may be cut with radiation from the laser. After cutting the fuse pattern, an electrical signal through the monitoring pattern may be measured to determine an alignment of the laser with respect to the fuse pattern.

The integrated circuit device may also include a fuse electrically coupled to a memory array having a plurality of primary memory cell blocks and a redundant memory cell block. The fuse may then be cut with radiation from the laser to replace a defective memory cell from the primary memory cell blocks with a memory cell from the redundant memory cell block after measuring the electrical signal to determine an alignment of the laser with respect to the fuse pattern. After measuring the electrical signal to determine an alignment of the laser, an alignment of the laser may be adjusted before cutting the fuse. Moreover, the fuse pattern may be electrically isolated.

The monitoring pattern may include first and second monitoring patterns with the fuse pattern between the first and second monitoring patterns, and measuring an electrical signal may include measuring a first electrical signal through the first monitoring pattern and measuring a second electrical signal through the second monitoring pattern. The fuse pattern and the first and second monitoring patterns may be parallel, or the first and second monitoring patterns may be perpendicular with respect to the fuse pattern.

The monitoring pattern may include first and second monitoring patterns arranged on opposite sides of the fuse pattern in a first direction, and third and fourth monitoring patterns arranged on opposite sides of the fuse pattern in a second direction different than the first direction. Moreover, measuring an electrical signal may include measuring a first electrical signal through the first monitoring pattern, measuring a second electrical signal through the second monitoring pattern, measuring a third electrical signal through the third monitoring pattern, and measuring a fourth electrical signal through the fourth monitoring pattern. In addition, the fuse pattern and the first and second monitoring patterns may be parallel, and the third and fourth monitoring patterns may be perpendicular with respect to the fuse pattern.

According to some other embodiments of the present invention, an integrated circuit device may include a fuse pattern, and a monitoring pattern adjacent the fuse pattern. More particularly, the fuse pattern and the monitoring pattern may both be configured to be cut responsive to laser radiation incident thereon, and the monitoring pattern may be configured to receive an electrical signal used to determine an alignment of a fuse cutting laser with respect to the fuse pattern.

In addition, a memory array may have a plurality of primary memory cell blocks and a redundant memory cell block, and a fuse may be electrically coupled to the memory array. The memory array may be configured to replace a defective memory cell from the primary memory cell blocks with a memory cell from the redundant memory cell block responsive to a state of the fuse. Moreover, the fuse pattern may be electrically isolated.

The monitoring pattern may include first and second monitoring patterns with the fuse pattern between the first and second monitoring patterns, and the monitoring pattern may be configured to receive a first electrical signal through the first monitoring pattern and to receive a second electrical signal through the second monitoring pattern. The fuse pattern and the first and second monitoring patterns may be parallel, or the first and second monitoring patterns may be perpendicular with respect to the fuse pattern.

According to some embodiments of the present invention, a monitoring fuse structure may be used to monitor laser alignment.

According to some embodiments of the present invention, a monitoring fuse structure of a semiconductor device may be used to monitor laser alignment. The monitoring fuse structure may include a fuse pattern with fuses having a first width and a first length and which may be cut by laser irradiation. A monitoring pattern may be spaced apart from the fuse pattern to monitor laser alignment at least in one direction of a width or length direction of the fuse pattern.

The fuse pattern may be in an electrically floating state, and a signal having a predetermined level may be provided to the monitoring pattern. The monitoring pattern may include a pair of patterns arranged symmetrically with respect to the fuse pattern with the fuse pattern between the monitoring patterns in the length direction of the fuse pattern, to monitor an alignment of the laser irradiated to the fuse pattern in the length direction of the fuse pattern.

The monitoring pattern may include a first pattern having a first body arranged at a first interval from one end of the fuse pattern, extending in the width direction of the fuse pattern, and having a second width and a second length. A first pair of legs may extend in the length direction of the fuse pattern from both ends of the first body. A second pattern may include a second body arranged at a second interval from the other end of the fuse pattern, extending in the width direction of the fuse pattern, and having a third width and a third length, and a second pair of legs extending in the length direction of the fuse pattern from both ends of the second body.

The monitoring pattern may include a pair of patterns arranged symmetrically with respect to the fuse pattern with the fuse pattern between the monitoring patterns in the width direction of the fuse pattern, to monitor an alignment of the laser irradiated to the fuse pattern in the width direction of the fuse pattern. The monitoring pattern may include a first pattern arranged at a third interval from the fuse pattern in the width direction of the fuse pattern, extending in the length direction of the fuse pattern, and having a fourth width and a fourth length, and a second pattern arranged at a fourth interval from the fuse pattern in the width direction of the fuse pattern, extending in the length direction of the fuse pattern, and having a fifth width and a fifth length.

The monitoring pattern may include a first pair of patterns arranged symmetrically with respect to the fuse pattern with the fuse pattern between the monitoring patterns in the length direction of the fuse pattern, to monitor an alignment of the laser irradiated to the fuse pattern, in the length direction of the fuse pattern. A second pair of patterns may be arranged symmetrically with respect to the fuse pattern with the fuse pattern between the monitoring patterns in the width direction of the fuse pattern to monitor an the alignment of the laser irradiated to the fuse pattern, in the width direction of the fuse pattern.

According to some other embodiments of the present invention, a semiconductor memory device may include a monitoring fuse to monitor laser alignment. The device may include a memory cell block including a plurality of memory cells, a redundant memory cell block including a plurality of redundant memory cells, and a plurality of input pads to provide address and command signals to the memory cell block and the redundant cell block. The device may also include a fuse box including a plurality of first fuses each having a first width which may be cut by a laser to replace a defective memory cell of the plurality of memory cells in the memory cell block with the redundant memory cell in the redundant memory cell block. In addition a signature fuse box may include a plurality of second fuses and may store information of the semiconductor device depending on whether or not the second fuse is cut. The signature fuse box may include a monitoring fuse to monitor alignment of the laser used to cut the first fuse in the fuse box.

The monitoring fuse may include a fuse pattern having a second width and a second length and the fuse pattern may be in an electrically floating state and may be cut by laser irradiation. A monitoring pattern may be spaced apart from the fuse pattern to monitor laser alignment at least in one direction of a length or width direction of the fuse pattern, with a signal of a predetermined level being provided to the monitoring pattern.

The monitoring pattern may include a pair of patterns arranged symmetrically with respect to the fuse pattern with the fuse pattern between the monitoring patterns in the length direction of the fuse pattern, to monitor an alignment of a laser irradiated to the fuse pattern, in the length direction of the fuse pattern. Each pattern may include a body arranged at a predetermined interval from one end of the fuse pattern, extending in the width direction of the fuse pattern, and having a third width and a second length, and a first pair of legs extending in the length direction of the fuse pattern from both ends of the body.

The monitoring pattern may include a pair of patterns arranged symmetrically with respect to the fuse pattern with the fuse pattern between the monitoring patterns in the width direction of the fuse pattern to monitor an alignment of the laser irradiated to the fuse pattern, in the width direction of the fuse pattern. Each pattern may be arranged at a predetermined interval from one end of the fuse pattern, extending in the length direction of the fuse pattern, and having a fourth width and a third length. Signals from the input pad may be provided at opposite levels to both ends of the patterns, respectively.

The monitoring pattern may include a first pair of patterns arranged symmetrically with respect to the fuse pattern with the fuse pattern between the monitoring patterns in the length direction of the fuse pattern, to monitor an alignment of the laser irradiated to the fuse pattern, in the length direction of the fuse pattern. A second pair of patterns may be arranged symmetrically with respect to the fuse pattern with the fuse pattern between the monitoring patterns in the width direction of the fuse pattern, to monitor an alignment of the laser irradiated to the fuse pattern, in the width direction of the fuse pattern. The first pair of patterns may include a body arranged at a predetermined interval from one end of the fuse pattern, extending in the width direction of the fuse pattern, and having a third width and a second length, and a pair of legs extending in the length direction of the fuse pattern from both ends of the body, wherein signals from the input pad are provided at opposite levels to the pair of legs, respectively. The second pair of patterns may be arranged at a predetermined interval from the fuse pattern, extending in the length direction of the fuse pattern, and have a fourth width and a third length, wherein signals from the input pad are provided at opposite levels to both ends of the patterns, respectively.

According to still other embodiments of the present invention, a laser alignment monitoring circuit for a semiconductor device may include a fuse pattern cut by laser irradiation, and a monitoring pattern spaced apart from the fuse pattern, to monitor laser alignment in at least one direction of a length or width direction of the fuse pattern, and first and second signals may be provided to first and second nodes of the monitoring pattern, respectively. The laser alignment monitoring circuit may include a first transfer gate to transfer the first signal to be provided to the first node in response to a control signal and an inverted control signal, and a second transfer gate to transfer the second signal to be provided to the second node in response to the control signal and the inverted control signal. The first and second signals may be transferred to a resistor having two terminals by the first and second transfer gates, respectively. A tester may monitor the laser alignment by measuring an amount of change of current flowing through the resistor, and a logic gate may receive a signal from the tester and may provide the control signal and the inverted control signal.

### BRIEF DESCRIPTION OF THE DRAWINGS

FIG. 1 is a plan view illustrating a fuse box of a conventional semiconductor device.

FIG. 2 is a view illustrating a bridge formed when a fuse is cut in a fuse box of the conventional semiconductor device of FIG. 1.

FIG. 3A is a plan view illustrating a laser alignment monitoring fuse in a semiconductor device according to some embodiments of the present invention.

FIG. 3B is a plan view illustrating a laser alignment monitoring fuse in a semiconductor device according to some other embodiments of the present invention.

FIG. 3C is a plan view illustrating a laser alignment monitoring fuse in a semiconductor device according to still other embodiments of the present invention.

FIG. 4A is a diagram illustrating a configuration of a laser alignment monitoring circuit in a semiconductor device according to some embodiments of the present invention.

FIG. 4B is a diagram illustrating a configuration of a laser alignment monitoring circuit in a semiconductor device according to some other embodiments of the present invention.

FIG. 4C is a diagram illustrating a configuration of a laser alignment monitoring circuit in a semiconductor device according to some other embodiments of the present invention;

FIG. 5 is a block diagram illustrating a semiconductor memory device having laser alignment monitoring fuses according to some other embodiments of the present invention.

FIG. 6 is a plan view illustrating a signature fuse box in the semiconductor memory device of FIG. 5.

### DETAILED DESCRIPTION

The present invention is described more fully hereinafter with reference to the accompanying drawings, in which embodiments of the present invention are shown. This invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity. Like numbers refer to like elements throughout.

It will be understood that when an element or layer is referred to as being “on”, “connected to” or “coupled to” another element or layer, it can be directly on, connected or coupled to the other element, or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Also, as used herein, “lateral” refers to a direction that is substantially orthogonal to a vertical direction.

The terminology used herein is for the purpose of describing particular embodiments only, and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a photolithographically patterned structure may, typically, have rounded or curved features at its corners rather than a 90 degree angles. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. Accordingly, these terms can include equivalent terms that are created after such time. It will be further understood that terms, such as those defined in commonly used dictionaries, should be interpreted as having a meaning that is consistent with their meaning in the present specification and in the context of the relevant art, and will not be interpreted in an idealized or overly formal sense unless expressly so defined herein. All publications, patent applications, patents, and other references mentioned herein are incorporated by reference in their entirety.

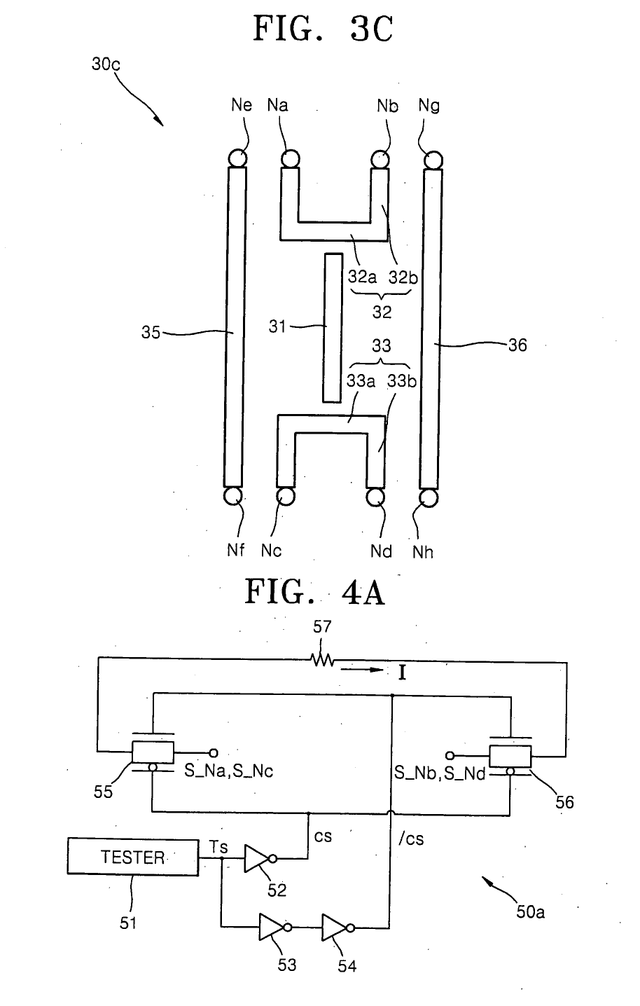

FIG. 3A is a plan view illustrating a monitoring fuse used to monitor an alignment of a fuse cutting laser in a semiconductor device according to some embodiments of the present invention. Referring to FIG. 3A, a monitoring fuse 30a is a fuse to monitor laser alignment in a length direction of a fuse. The monitoring fuse 30a includes a fuse pattern 31 to be cut by a laser beam and a pair of monitoring patterns 32 and 33. The fuse pattern 31 has a first width W3 and a first length L3 and is in an electrically floating state. In other words, the fuse pattern 31 may be electrically decoupled from any other conductors and/or electronic elements of the semiconductor memory device. The first width W3 and the first length L3 of the fuse pattern 31 may be provided in accordance with a spot size of the laser beam. The monitoring patterns 32 and 33 are patterns used to monitor an alignment of the laser beam irradiated to the fuse pattern 31, and may be spaced apart from the fuse pattern 31. The fuse pattern 31 and the first monitoring pattern 32 are arranged at a first interval d1, and the fuse pattern 31 and the second monitoring pattern 33 are arranged at a second interval d2. The first interval d1 and the second interval d2 may be equal. The first interval d1 and the second interval d2 may be determined in consideration of an alignment error of the laser beam. The fuse pattern 31 and the monitoring patterns 32 and 33 of the monitoring fuse 30a may be made of aluminum.

The monitoring patterns 32 and 33 are arranged symmetrically with respect to the fuse pattern 31 which is between the monitoring patterns in a length direction of the fuse pattern 31. The first monitoring pattern 32 includes a first body 32a extending in a width direction of the fuse pattern 31, and a first pair of legs 32b extending in a length direction of the fuse pattern 31 from both ends of the first body 32a and in parallel with respect to each other. The second monitoring pattern 33 includes a second body 33a extending in a width direction of the fuse pattern 31 and arranged in parallel with the first body 32a, and a second pair of legs 32b extending in a length direction of the fuse pattern 31 from both ends of the second body 33a and in parallel with each other. The first and second bodies 32a and 33a of the first and second monitoring patterns 32 and 33 may have the second width W4 and the second length L4. The second width W4 of the first and second bodies 32a and 33a may be equal to the first width W3 of the fuse pattern 31. The second length L4 may be greater than the first width W3.

The first pair of legs 32b of the first monitoring fuse pattern 32 are connected to first and second nodes Na and Nb, respectively, and are provided with electrical signals. The electrical signals applied to the first node Na and the second node Nb may have different levels. The second pair of legs 33b of the second monitoring fuse pattern 33 are connected to third and fourth nodes Nc and Nd, respectively, and provided with electrical signals. The electrical signals applied to the third node Nc and the fourth node Nd may have different levels. If the laser beam is not misaligned when cutting the fuse pattern 31 with a laser beam, only the fuse pattern 31 is cut and the first and second monitoring patterns 32 and 33 are not affected. On the other hand, if the laser beam is misaligned in the length direction of the fuse pattern 31, the fuse pattern 31 may be cut and the first and/or the second monitoring patterns 32 and/or 33 may be irradiated (and thus cut) by the laser beam.

FIG. 3B is a plan view illustrating a monitoring fuse used to monitor an alignment of a fuse cutting laser in a semiconductor device according to other embodiments of the present invention. Referring to FIG. 3B, a monitoring fuse 30b is a fuse used to monitor laser alignment in a width direction of the fuse. The monitoring fuse 30b includes a fuse pattern 31 to be cut by a laser beam and a pair of monitoring patterns 35 and 36. The fuse pattern 31 has a first width W3 and a first length L3 and may be in an electrically floating state. In other words, the fuse pattern 31 may be electrically decoupled from any other conductors and/or electronic elements of the semiconductor memory device. The third and fourth monitoring patterns 35 and 36 are patterns used to monitor an alignment of the laser beam irradiated to the fuse pattern 31, and are arranged at third and fourth intervals d3 and d4, respectively. The third interval d3 and the fourth interval d4 may be the same and may be determined in consideration of an alignment error of the laser. The third and fourth monitoring patterns 35 and 36 are arranged symmetrically with respect to the fuse pattern 31 with the fuse pattern between the monitoring patterns in a width direction of the fuse pattern 31 and may have a third width W5 and a third length L5. The third and fourth monitoring patterns 35 and 36 are arranged in parallel with respect to the fuse pattern 31 in a length direction of the fuse pattern 31. The third width W5 of the third and fourth monitoring patterns 35 and 36 may be equal to the first width W3 of the fuse pattern 31 and the third length L5 may be greater than the first length L3 of the fuse pattern 31. Ends of the third monitoring fuse pattern 35 are connected to fifth and sixth nodes Ne and Nf, respectively, and are provided with electrical signals. The electrical signals applied to the fifth and sixth nodes Ne and Nf may have different levels. Ends of the fourth monitoring fuse pattern 36 are connected to seventh and eighth nodes Ng and Nh, respectively, and are provided with electrical signals. The electrical signals applied to the seventh and eighth nodes Ng and Nh may have different levels.

If the laser beam is not misaligned when cutting the fuse pattern 31, only the fuse pattern 31 is cut and the third and fourth monitoring patterns 35 and 36 are not affected. On the other hand, if the laser beam is misaligned in the width direction of the fuse pattern 31, the fuse pattern 31 may be cut and the third and/or fourth monitoring patterns 35 and/or 36 may be irradiated (and thus cut) by the laser beam.

FIG. 3C is a plan view illustrating a monitoring fuse used to monitor an alignment of a fuse cutting laser in a semiconductor device according to still other embodiments of the present invention. Referring to FIG. 3C, a monitoring fuse 30c is a fuse used to monitor laser alignment in length and width directions of the fuse. The monitoring fuse 30c includes a fuse pattern 31 to be cut by a laser beam and two pairs of monitoring patterns 32 and 33, and 35 and 36. The fuse pattern 31 has a first width W3 and a first length L3 and is in an electrically floating state. The first width W3 and the first length L3 of the fuse pattern 31 may depend on a spot size of the laser beam. The first pair of monitoring patterns 32 and 33 are patterns used to monitor laser alignment in the length direction of the fuse pattern 31 as discussed above with respect to FIG. 3A. The second pair of monitoring patterns 35 and 36 are patterns used to monitor laser alignment in the width direction of the fuse pattern 31 as discussed above with respect to FIG. 3B.

If the laser beam is not misaligned when cutting the fuse pattern 31 with the laser beam, only the fuse pattern 31 is cut and the first and second monitoring patterns 32 and 33 and the third and fourth monitoring patterns 35 and 36 may not be affected. On the other hand, if the laser beam is misaligned in the length direction of the fuse pattern 31, the fuse pattern 31 may be cut and the first and/or second monitoring patterns 32 and/or 33 may be irradiated with the laser beam. If the laser beam is misaligned in the width direction of the fuse pattern 31, the fuse pattern 31 may be cut and the third and/or fourth monitoring patterns 35 and/or 36 may be irradiated with the laser beam. Furthermore, if the laser beam is misaligned in the length and width directions of the fuse pattern 31, the fuse pattern 31 may be cut and the first and/or second monitoring patterns 32 and/or 33 and the third and/or fourth monitoring patterns 35 and/or 36 may be affected.

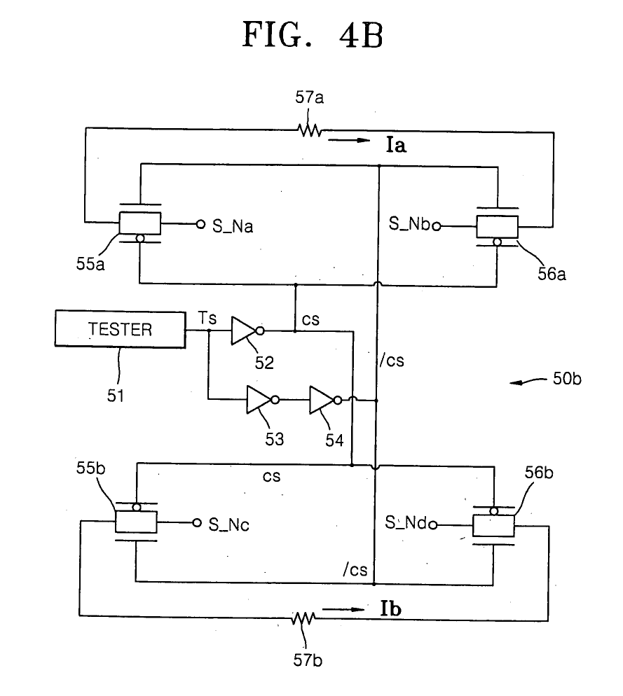

FIG. 4A illustrates a monitoring circuit used to monitor laser alignment using a monitoring fuse according to embodiments of the present invention. A laser alignment monitoring circuit 50a is configured to monitor laser alignment using the monitoring fuse 32a of FIG. 3A or the monitoring fuse 32b of FIG. 3B. Referring to FIG. 4A, the laser alignment monitoring circuit 50a may first measure an alignment with respect to one of the first and second monitoring fuses 32 and 33 or the third and fourth monitoring fuses 35 and 36 and may then measure the alignment with respect to the other. In FIG. 4A, the monitoring fuse 30a of FIG. 3A is only an example.

Referring to FIG. 4A, the monitoring circuit 50a includes a control signal generating unit, a transfer unit, and an alignment measuring unit. The control signal generating unit includes a first inverter 52 to receive a test mode signal TS from a tester 51 and to generate a first control signal cs, and second and third inverters 53 and 54 to receive a test mode signal TS and to generate a second control signal /cs having a reverse phase with respect to the first control signal cs. The transfer unit includes a transfer gate 55 to provide a first measure signal S_Na or a third measure signal S_Nc to be applied to the first node Na or the third node Nc of the monitoring fuse 30a, to one end of the alignment measuring unit in response to the first and second control signals cs and /cs; and a transfer gate 56 to provide a second measure signal S_Nb or a fourth measure signal S_Nd to be applied to the second node Nb or the fourth node Nd of the monitoring fuse 30a, to the other end of the alignment measuring unit in response to the first and second control signals cs and /cs. The alignment measuring unit includes a resistor 57 having two terminals to which the first or third measure signal S_Na or S_Nc and the second or fourth measure signal S_Nb or S_Nd are provided, respectively. The first and second measure signals S_Na and S_Nb may have opposite levels. That is, the first measure signal S_Na may be a high signal and the second measure signal S_Nb may be a low signal, and vice versa. The third and fourth measure signals S_Nc and S_Nd may have opposite levels. The third measure signal S_Nc may be a high signal and the fourth measure signal S_Nd may be a low signal, or vice versa.

The tester 51 outputs the test mode signal TS. The test mode signal TS may be, for example, a signal generated in a mode register set (MRS) mode in an electric die sorting (EDS) test process in which it is examined if a memory cell in a wafer state is defective. If the test mode signal TS is high, the first control signal cs from the first inverter 52 is low and the second control signal /cs from the second and third inverters 53 and 54 is high. Accordingly, the first transfer gate 55 and the second transfer gate 56 are turned on and the first measure signal S_Na and the second measure signal S_Nb to be provided to the first node Na and the second node Nb of the monitoring fuse 32a are provided to both terminals of the resistor 57, respectively.

Accordingly, if the laser beam is irradiated within an alignment error tolerance relative to the fuse pattern 31 in the monitoring fuse 32a of FIG. 3A, the fuse pattern 31 is cut and the monitoring patterns 32 and 33 are not significantly affected. Accordingly, the first and second nodes Na and Nb or the third and fourth nodes Nc and Nd of the monitoring fuse 32a are connected to respective terminals of the resistor 57. In this case, the measure signal S_Na or S_Nc of a high level is applied to the first node Na or the third node Nc and the measure signal S_Nb or S_Nd of a low level is applied to the second node Nb or the fourth node Nd, and current I flows through the resistor 57. The tester 51 detects the current I flowing through the resistor 57 and determines whether the laser beam is misaligned based on an amount of the current. If there is no significant change in the current I flowing through the resistor 57, the tester 51 determines that the laser alignment is not out of the alignment error tolerance.

On the other hand, when the laser beam irradiated on the fuse pattern 31 is significantly misaligned in the length direction of the fuse pattern 31 out of the alignment error tolerance, it may be irradiated not only on the fuse pattern 31 but also on the first and/or second monitoring patterns 32 and 33. Accordingly, the current I flowing through the first and/or second monitoring patterns 32 and/or 33 may be changed so that the tester 51 may determine a misalignment degree of the laser beam based on an amount of the changed current. Similarly, in the case where the monitoring fuse 30b of FIG. 3B is applied, when the laser beam is significantly misaligned in the width direction of the fuse pattern 31 out of the alignment error tolerance and is irradiated on the fuse pattern 31, it may be irradiated not only on the fuse pattern 31 but also on the third and/or fourth monitoring patterns 35 and/or 36. Accordingly, current I flowing through the third and/or fourth monitoring patterns 35 and/or 36 may be changed so that the tester 51 may determine a misalignment degree of the laser beam based on an amount of the changed current. The first and/or second monitoring patterns 32 and/or 33 and/or the third and/or fourth monitoring patterns 35 and/or 36 may be cut when the laser beam is significantly misaligned. In this case, the first and/or second monitoring patterns 32 and/or 33 and/or the third and/or fourth monitoring patterns 35 and/or 36 are open-circuited.

FIG. 4B illustrates a monitoring circuit configured to monitor laser alignment using a monitoring fuse according to embodiments of the present invention. In FIG. 4B, the laser alignment monitoring circuit 50b monitors laser alignment using the monitoring fuse 32a of FIG. 3A and/or the monitoring fuse 32b of FIG. 3B. Referring to FIG. 4B, the laser alignment monitoring circuit 50b can simultaneously measure laser alignment with respect to the first and second monitoring fuses 32 and 33 and the third and fourth monitoring fuses 35 and 36. In FIG. 4B, the monitoring fuse 30a of FIG. 3A may be used.

The monitoring circuit 50b includes transfer gates 55a and 56a and a resistor 57a used to measure alignment with respect to the first or third monitoring fuse 32 or 35, and transfer gates 55b and 56b and a resistor 57b used to measure alignment with respect to the second or fourth monitoring fuse 33 or 36, in which current Ia or Ib flowing through each resistor 57a or 57b is measured as an alignment measurement. Other features are the same as the monitoring circuit 50a of FIG. 4A.

FIG. 4C illustrates a monitoring circuit configured to monitor laser alignment using the monitoring fuse 30c shown in FIG. 3C. Referring to FIG. 4C, a laser alignment monitoring circuit 50c can simultaneously measure alignment with respect to the first and second monitoring fuses 32 and 33 and the third and fourth monitoring fuses 35 and 36. In FIG. 4C, the monitoring fuse 30c of FIG. 3C is only an example. The monitoring circuit 50c includes transfer gates 55a to 55d and 56a to 56d and resistors 57a to 57d used to measure alignment with respect to the first to fourth monitoring fuses 32, 33, 35, and 36, in which currents Ia to Id flowing through the respective resistors 57a to 57d are measured to determine alignment. Other features are the same as the monitoring circuit 50a of FIG. 4A.

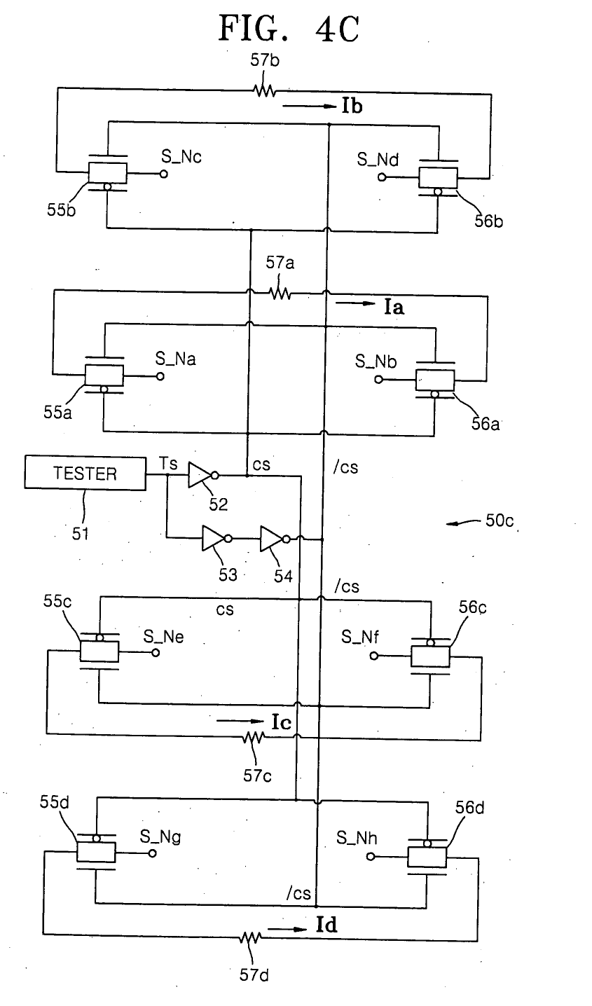

FIG. 5 is a block diagram illustrating a configuration of a semiconductor memory device according to some embodiments of the present invention. Referring to FIG. 5, a semiconductor memory device 60 includes a memory cell block 61 having a plurality of memory cell blocks (each having a plurality of memory cells), a redundant memory cell block 62 having a plurality of redundant memory cells, a plurality of first input pads A1 to An configured to provide an address signal to the memory cell block and the redundant cell block, and a plurality of second input pads COM configured to provide a command signal. The second input pads COM may include a number of pads configured to provide various commands used to drive the semiconductor device 60. The semiconductor memory device 60 may also include a fuse box 63 used to replace a defective memory cell or cells of the plurality of memory cells in the memory cell block with a corresponding redundant memory cell or cells in the redundant memory cell block, and a signature fuse box 64 used to store information of the semiconductor device depending on whether or not a fuse is cut.

The signature fuse box 64 may receive relevant input signals Ai to Ap from first input pads A1 to An and may provide a measure signal to the first to eighth nodes Na to Nh of the monitoring fuses 30a, 30b and/or 30c. A need for separate input pads to provide the measure signal to the monitoring fuses 30a, 30b and 30c may thus be reduced. The second input pad or pads COM may be used to provide the measure signal to the monitoring fuses 30a, 30b and 30c.

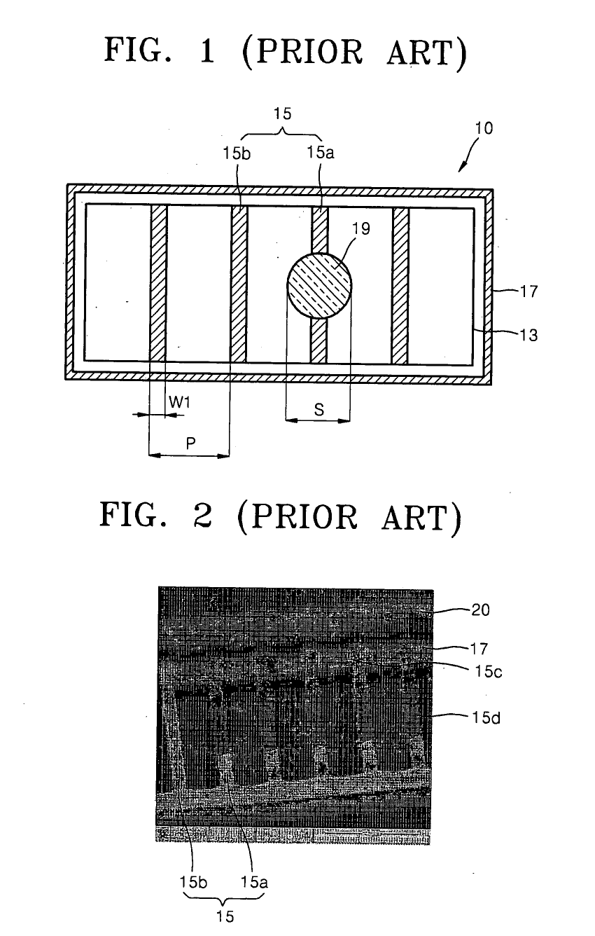

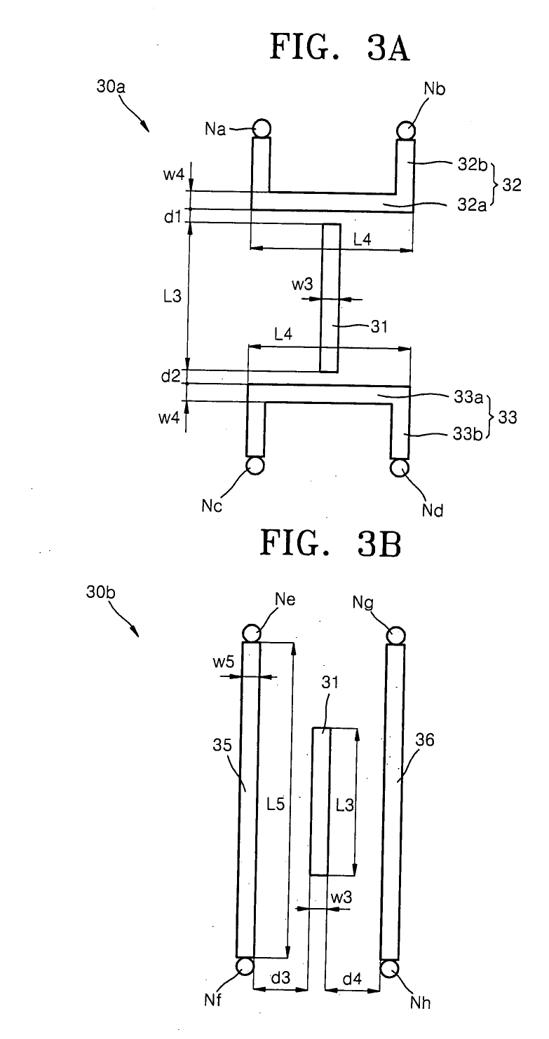

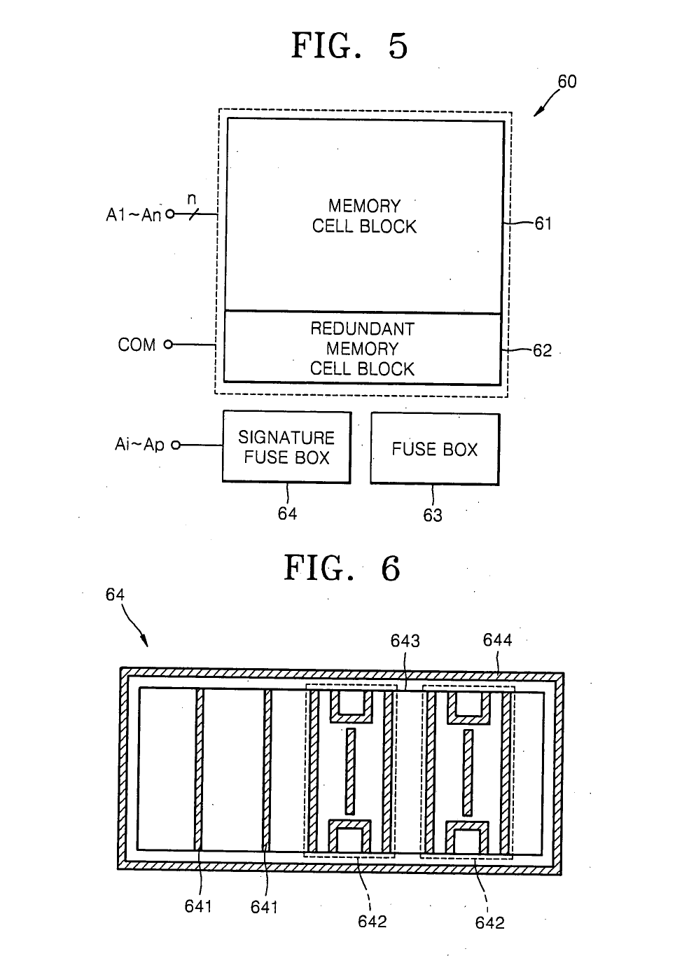

The fuse box 63 may have the configuration as shown in FIG. 1. Referring to FIG. 6, the signature fuse box 64 stores information for a semiconductor device or a semiconductor package including the semiconductor device depending on whether one or more of the signal fuses 641 is cut. The signature fuse box 64 includes signal fuses 641 configured to store information for the semiconductor device, and monitoring fuses 642. Each monitoring fuse 642 may include any one of the monitoring fuses 30a to 30c of FIGS. 3A through 3C. In FIG. 6, 643 denotes a fuse opening, and 644 denotes a metal interconnection.

According to some embodiments of the present invention, since the monitoring fuses are arranged in the signature fuse box 64 and provided with electrical signals using input pads that provide the address and command signals to the memory cell block 61, a configuration of the device may be simplified. In addition, it may be unnecessary to scale down a pitch of the fuses in the fuse box 63. Although the monitoring fuses have been illustrated as being arranged inside the signature fuse box 63, they may be arranged at other positions within the memory device.

According to embodiments of the present invention described above, monitoring fuses capable of monitoring an alignment of the laser beam irradiated to fuses in the fuse box may be provided. Thus, it may be possible to monitor, in advance, a degree of laser alignment and/or misalignment of equipment used to cut the fuses in the fuse box and to reduce cutting defects of the fuses by cutting the fuses in the fuse box based on the monitored alignment degree. Furthermore, the monitoring fuses may be disposed inside the signature fuse box. Thus, it may be possible to reduce any scaling down of a pitch of fuses in the fuse box that may otherwise be required due to a presence of the monitoring fuses. Furthermore, laser alignment of laser cutting equipment may be measured in advance using a laser alignment monitoring fuse, alignment may be corrected based on the alignment measurement, and then fuses in the fuse box may be cut to repair a defective memory cell(s)/block(s). Thus, cutting defects may be reduced and/or yield of semiconductor devices may be improved.

While the present invention has been particularly shown and described with reference to embodiments thereof, it will be understood by those of ordinary skill in the art that various changes in form and details may be made therein without departing from the spirit and scope of the present invention as defined by the following claims.

What is claimed is:

1. A method of determining an alignment of a laser with respect to an integrated circuit device including a fuse pattern and a monitoring pattern adjacent the fuse pattern, the method comprising:
cutting the fuse pattern with radiation from the laser; and
after cutting the fuse pattern, measuring an electrical signal through the monitoring pattern to determine an alignment of radiation from the laser with respect to the fuse pattern.

2. A method according to claim 1 wherein the integrated circuit device further includes a fuse electrically coupled to a memory array having a plurality of primary memory cell blocks and a redundant memory cell block, the method further comprising:
after measuring the electrical signal to determine an alignment of the laser with respect to the fuse pattern, cutting the fuse with radiation from the laser to replace a defective memory cell from the primary memory cell blocks with a memory cell from the redundant memory cell block.

3. A method according to claim 2 further comprising:
after measuring the electrical signal to determine an alignment of the laser, adjusting an alignment of the laser before cutting the fuse.

4. A method according to claim 2 wherein the fuse pattern is electrically isolated.

5. A method according to claim 1 wherein the monitoring pattern includes first and second monitoring patterns with the fuse pattern between the first and second monitoring patterns, and wherein measuring an electrical signal includes measuring a first electrical signal through the first monitoring pattern and measuring a second electrical signal through the second monitoring pattern.

6. A method according to claim 5 wherein the fuse pattern and the first and second monitoring patterns are parallel.

7. A method according to claim 5 wherein the first and second monitoring patterns are perpendicular with respect to the fuse pattern.

8. A method according to claim 1 wherein the monitoring pattern includes first and second monitoring patterns arranged on opposite sides of the fuse pattern in a first direction, wherein the monitoring pattern includes third and fourth monitoring patterns arranged on opposite sides of the fuse pattern in a second direction different than the first direction, and wherein measuring an electrical signal includes measuring a first electrical signal through the first monitoring pattern, measuring a second electrical signal through the second monitoring pattern, measuring a third electrical signal through the third monitoring pattern, and measuring a fourth electrical signal through the fourth monitoring pattern.

9. A method according to claim 8 wherein the fuse pattern and the first and second monitoring patterns are parallel, and wherein the third and fourth monitoring patterns are perpendicular with respect to the fuse pattern.

10. An integrated circuit device comprising:
a fuse pattern; and
a monitoring pattern adjacent the fuse pattern wherein the fuse pattern and the monitoring pattern are both configured to be cut responsive to laser radiation incident thereon and wherein the monitoring pattern is configured to receive an electrical signal used to determine an alignment of radiation from a fuse cutting laser with respect to the fuse pattern.

11. An integrated circuit device according to claim 10 further comprising:
a memory array having a plurality of primary memory cell blocks and a redundant memory cell block;
a fuse electrically coupled to the memory array wherein the memory array is configured to replace a defective memory cell from the primary memory cell blocks with a memory cell from the redundant memory cell block responsive to a state of the fuse.

12. An integrated circuit device according to claim 11 wherein the fuse pattern is electrically isolated.

13. An integrated circuit device according to claim 10 wherein the monitoring pattern includes first and second monitoring patterns with the fuse pattern between the first and second monitoring patterns, and wherein the monitoring pattern is configured to receive a first electrical signal through the first monitoring pattern and to receive a second electrical signal through the second monitoring pattern.

14. An integrated circuit device according to claim 13 wherein the fuse pattern and the first and second monitoring patterns are parallel.

15. An integrated circuit device according to claim 13 wherein the first and second monitoring patterns are perpendicular with respect to the fuse pattern.

16. A laser alignment monitoring fuse structure for a semiconductor device, the structure comprising:
a fuse pattern having a first width and a first length and which is configured to be cut by laser irradiation; and
a monitoring pattern spaced apart from the fuse pattern, configured to monitor laser alignment at least in one direction of a length or width direction of the fuse pattern.

17. The structure of claim 16, wherein the fuse pattern is in an electrically floating state, and a signal having a predetermined level is provide to the monitoring fuse.

18. The structure of claim 16, wherein the monitoring pattern comprises a pair of patterns arranged symmetrically with respect to the fuse pattern interposed therebetween in the length direction of the fuse pattern, for monitoring the alignment of the laser irradiated to the fuse pattern in the length direction of the fuse pattern.

19. The structure of claim 16, wherein the monitoring pattern comprises:
a first pattern including a first body arranged at a first interval from one end of the fuse pattern, extending in the width direction of the fuse pattern, and having a second width and a second length, and a first pair of legs extending in the length direction of the fuse pattern from both ends of the first body; and
a second pattern including a second body arranged at a second interval from the other end of the fuse pattern, extending in the width direction of the fuse pattern, and having a third width and a third length, and a second pair of legs extending in the length direction of the fuse pattern from both ends of the second body.

20. The structure of claim 16, wherein the monitoring pattern comprises a pair of patterns arranged symmetrically with respect to the fuse pattern interposed therebetween in the width direction of the fuse pattern, for monitoring the alignment of the laser irradiated to the fuse pattern in the width direction of the fuse pattern.

21. The structure of claim 16, wherein the monitoring pattern comprises:
a first pattern arranged at a third interval from the fuse pattern in the width direction of the fuse pattern, extending in the length direction of the fuse pattern, and having a fourth width and a fourth length; and
a second pattern arranged at a fourth interval from the fuse pattern in the width direction of the fuse pattern, extending in the length direction of the fuse pattern, and having a fifth width and a fifth length.

22. The structure of claim 16, wherein the monitoring pattern comprises:
a first pair of patterns arranged symmetrically with respect to the fuse pattern interposed therebetween in the length direction of the fuse pattern, configured to monitor the alignment of the laser irradiated to the fuse pattern in the length direction of the fuse pattern; and
a second pair of patterns arranged symmetrically with respect to the fuse pattern interposed therebetween in the width direction of the fuse pattern configured to monitor the alignment of the laser irradiated to the fuse pattern in the width direction of the fuse pattern.

23. A semiconductor memory device comprising:
a memory cell block including a plurality of memory cells;
a redundant memory cell block including a plurality of redundant memory cells;
a plurality of input pads configured to provide address and command signals to the memory cell block and the redundant cell block;
a fuse box including a plurality of first fuses each having a first width and which are cut by a laser to replace a defective memory cell of the plurality of memory cells in the memory cell block with the redundant memory cell in the redundant memory cell block; and
a signature fuse box including a plurality of second fuses and storing information of the semiconductor device depending on whether or not the second fuse is cut, wherein:
the signature fuse box comprises a monitoring fuse configured to monitor alignment of the laser used to cut the first fuse in the fuse box.

24. The device of claim 23, wherein the monitoring fuse comprises:
a fuse pattern having a second width and a second length, the fuse pattern being in an electrically floating state and configured to be cut by laser irradiation; and
a monitoring pattern spaced apart from the fuse pattern, configured to monitor laser alignment at least in one direction of a length or width direction of the fuse pattern, signals of a predetermined level being provided to the monitoring pattern.

25. The device of claim 24, wherein the monitoring pattern comprises a pair of patterns arranged symmetrically with respect to the fuse pattern interposed therebetween in the length direction of the fuse pattern configured to monitor the alignment of the laser irradiated to the fuse pattern, in the length direction of the fuse pattern,
each pattern includes a body arranged at a predetermined interval from one end of the fuse pattern, extending in the width direction of the fuse pattern, and having a third width and a second length, and a first pair of legs extending in the length direction of the fuse pattern from both ends of the body, and
signals from the input pads are provided at opposite levels to the first pair of legs, respectively.

26. The device of claim 24, wherein the monitoring pattern comprises a pair of patterns arranged symmetrically with respect to the fuse pattern interposed therebetween in the width direction of the fuse pattern, configured to monitor the alignment of the laser irradiated to the fuse pattern in the width direction of the fuse pattern,
each pattern is arranged at a predetermined interval from one end of the fuse pattern, extending in the length direction of the fuse pattern, and having a fourth width and a third length, and
signals from the input pads are provided at opposite levels to both ends of the patterns, respectively.

27. The device of claim 24, wherein the monitoring pattern comprises:
a first pair of patterns arranged symmetrically with respect to the fuse pattern interposed therebetween in the length direction of the fuse patterns configured to monitor the alignment of the laser irradiated to the fuse pattern in the length direction of the fuse pattern; and
a second pair of patterns arranged symmetrically with respect to the fuse pattern interposed therebetween in the width direction of the fuse pattern, configured to monitor the alignment of the laser irradiated to the fuse pattern in the width direction of the fuse pattern, and wherein:
the first pair of patterns comprise a body arranged at a predetermined interval from one end of the fuse pattern, extending in the width direction of the fuse pattern, and having a third width and a second length, and a first pair of legs extending in the length direction of the fuse pattern from both ends of the first body, wherein signals from the input pads are provided at opposite levels to the first pair of legs, respectively, and
the second pair of patterns are arranged at a predetermined interval from the fuse pattern, extending in the length direction of the fuse pattern, and have a fourth width and a third length, wherein signals from the input pads are provided at opposite levels to both ends of the patterns, respectively.

28. A laser alignment monitoring circuit for a semiconductor device which comprises a fuse pattern configured to be cut by laser irradiation, and a monitoring pattern spaced apart from the fuse pattern configured to monitor laser alignment at least in one direction of a length or width direction of the fuse pattern, wherein first and second signals are providing to first and second nodes of the monitoring pattern, respectively, the circuit comprising:
a transfer unit configured to transfer the first and second signals to be provided to the first and second nodes in response to a control signal and an inverted control signal;
a measuring unit having two terminals to which the first and second signals transferred by the transfer unit are provided, respectively;
a tester configured to receive an output signal from the measuring unit and to monitor the laser alignment; and
a control signal generating unit configured to receive a signal from the tester and to provide the control signal and the inverted control signal.

29. The circuit of claim 28, wherein the transfer unit comprises:
a first transfer gate configured to transfer the first signal to be provided to the first node in response to the control signal and the inverted control signal; and
a second transfer gate configured to transfer the second signal to be provided to the second node in response to the control signal and the inverted control signal.

30. The circuit of claim 29, wherein the measuring unit comprises a resistor having the two terminals to which the first and second signals transferred by the first and second transfer gates are provided, respectively, and allowing the laser alignment to be measured based on an amount of change of current in the monitoring fuse.
